(19) United States
(12) Patent Application Publication
(10) Pub. No.: US 2015/0020883 A1
(43) Pub. Date: Jan. 22, 2015

(54) SOLAR CELL INCLUDING MICRO LENS ARRAY

(71) Applicant: AJOU UNIVERSITY INDUSTRY COOPERATION FOUNDATION, Gyeonggi-do (KR)

(72) Inventors: Sang Sik Yang, Seoul (KR); Jae Jin Lee, Seoul (KR); Kee Keun Lee, Gyeonggi-do (KR); Min Woo Nam, Gyeonggi-do (KR)

(73) Assignee: AJOU UNIVERSITY INDUSTRY COOPERATION FUNDATIN, Gyeonggi-do (KR)

(21) Appl. No.: 14/381,330

(22) PCT Filed: Feb. 20, 2013
(86) PCT No.: PCT/KR2013/001307

§ 371 Date: Aug. 27, 2014

(30) Foreign Application Priority Data
Feb. 29, 2012 (KR) 10-2012-0021451
Aug. 22, 2012 (KR) 10-2012-0091702

(51) Int. Cl. H01L 31/0232; H01L 31/0203; H01L 31/0304

(52) U.S. Cl. CPC H01L 31/02325; H01L 31/0304; H01L 31/0203
USPC 136/259

(57) ABSTRACT

Provided is a solar cell including a condensing micro lens array. The solar cell includes a lower electrode, a photoactive layer including a top formed with an upper opaque metal grid electrode and a bottom end disposed on the lower electrode, the photoactive layer being formed of III-V compound semiconductors to absorb solar light to generate photo-electric conversion, and the micro lens array disposed to have a certain gap from the top of the photoactive layer and refracting incident solar light toward the photoactive layer.

### FIELD

The present invention relates to a solar cell, and more particularly, to a method of improving the optical absorption efficiency of a solar cell including a photoactive layer formed of III-V compound semiconductors using a condensing micro lens array.

### BACKGROUND

Solar cells may be classified into silicon solar cells, compound semiconductor solar cells, dye-sensitized solar cells, and organic solar cells. Compound semiconductor solar cells may be classified, according to materials, into III-V solar cells, II-III-VI solar cells, and II-VI solar cells.

Due to development of apparatuses for thin film vapor deposition such as metalorganic chemical vapor deposition (MOCVD) and molecular beam epitaxy (MBE), technology in the field of III-V compound semiconductors has rapidly advanced. Generally, III-V compound semiconductors have a direct bandgap energy structure and have a relatively higher absorption factor than those of other compound semiconductors. Accordingly, it is possible to increase light absorption efficiency of solar cells by using III-V compound semiconductors as materials of a photoactive layer. Among III-V compound semiconductors, gallium arsenic (GaAs) has been developed as materials of solar cells.

FIG. 1 illustrates a solar cell including a photoactive layer formed of GaAs.

Referring to FIG. 1, a current generated from a solar light absorbed in a photoactive layer 4 and passing through a photo-electric conversion process may be supplied to one of a battery (not shown) and an electronic device (not shown) through power lines (not shown) connected to an upper electrode 2 and a lower electrode 3, respectively. To protect the photoactive layer 4, a sealing member 6 surrounds the photoactive layer 4. To protect the solar cell from an external environment, flat glass or transparent high polymers are generally used as a cover 1 to seal the solar cell. According to this, in the solar cell, a loss in efficiency inevitably occurs in the upper electrode 2. A loss of solar light reflected by the upper electrode 2 exists and the solar light is not fully absorbed in a shade area 5 formed on a bottom of the upper electrode 2, thereby preventing an active light current generation process. Accordingly, efficiency of photo-electric conversion decreases.

### DETAILED DESCRIPTION

### Technical Problem

The present invention provides a solar cell including a micro lens array disposed on a top of a photoactive layer formed with an upper opaque metal grid electrode and forming a certain gap from the top of the photoactive layer to reduce a spot area of solar light.

### Technical Solution

According to an aspect of the present invention, there is provided a solar cell including a condensing micro lens array. The solar cell includes a lower electrode, a photoactive layer including a top formed with an upper opaque metal grid electrode and a bottom end disposed on the lower electrode, the photoactive layer being formed of III-V compound semiconductors to absorb solar light to generate photo-electric conversion, and the micro lens array disposed to have a certain gap from the top of the photoactive layer and refracting incident solar light toward the photoactive layer.

The gap between the photoactive layer and the micro lens array may be identical to a distance between the top of the photoactive layer and a height of the micro lens array to reduce an area of a spot formed on the top of the photoactive layer by allowing the micro lens array to refract the solar light incident upon the micro lens array.

The micro lens array may include a plurality of micro lenses having a truncated spherical shape refracting solar light incident upon a top surface of the micro lens array.

The plurality of micro spherical lenses may be formed on the top surface of the micro lens array to allow a distance between adjacent micro spherical lenses to be “0”, respectively.

A gap between a bottom surface of the micro lens array formed with the plurality of micro spherical lenses and the top of the photoactive layer may be 900 μm.

The micro lens array may include a plurality of micro lenses having a truncated cylindrical shape refracting solar light incident upon a top surface of the micro lens array.

The plurality of micro cylindrical lenses may be formed on the top surface of the micro lens array to allow a distance between adjacent micro cylindrical lenses to be “0”, respectively.

A gap between a bottom surface of the micro lens array formed with the plurality of micro cylindrical lenses and the top of the photoactive layer may be 600 μm.

The solar cell may further include a sealing member, formed on the lower electrode, surrounding the photoactive layer and the micro lens array and transmitting solar light.

The micro lens array may be disposed to be closely coupled with an inner surface of the sealing member and to form a gap from the top of the photoactive layer.

The solar cell may further include an optical spacer including a top closely attached to the bottom surface of the micro lens array and a bottom closely attached to the top of the photoactive layer to support micro lens array to allow the micro lens array to be disposed to form the certain gap from the top of the photoactive layer.

### Advantageous Effects

According to the embodiments, a solar cell may include a condensing micro lens array disposed on a top of a photoactive layer formed with an upper opaque metal grid electrode and forming a certain gap from the top of the photo active layer to reduce a spot area of solar light, thereby condensing solar light heading for the upper opaque metal grid electrode into an area of the photoactive layer between electrodes to increase an amount of photons.

### BRIEF DESCRIPTION OF THE DRAWINGS

FIG. 1 is a configuration diagram of a general solar cell;

FIG. 2 is a cross-sectional view of a solar cell including a condensing micro lens array according to an embodiment of the present invention;

FIG. 3 is a photograph illustrating a focus formed on a charge-coupled device (CCD) by parallel rays passing through the micro lens array shown in FIG. 2;

FIG. 4 is a view illustrating sizes of spot areas according to focal lengths;

FIG. 5 is a view of a grid electrode according to an embodiment of the present invention;

FIG. 6 is a view of a grid electrode according to another embodiment of the present invention;

FIG. 7 illustrates current-voltage characteristic curves of solar cells mounted with a condensing micro lens arrays; and

FIG. 8 illustrates current density and efficiency variation curves in the solar cell according to heights according to certain gaps between a micro lens array and a top surface of a photoactive layer.

### MODE FOR CARRYING OUT THE INVENTION

Hereinafter, exemplary embodiments of the present invention will be described in detail with reference to the attached drawings.

The embodiments of the present invention are provided to more perfectly explain the present invention to a person of ordinary skill in the art. The following embodiments may be modified into various other forms, and the scope of the present invention is not limited to following embodiments. The embodiments are provided to allow the present disclosure to be more faithful and full and to perfectly transfer the inventive concept to those skilled in the art.

Terms used herein are to describe particular embodiments but will not limit the present invention. As used herein, the singular forms “a,” “an” and “the” are intended to include the plural forms as well, unless the context clearly indicates otherwise. It will be further understood that the terms “comprises” and/or “comprising” used herein specify the presence of stated shapes, numbers, operations, elements, and/or a group thereof, but do not preclude the presence or addition of one or more other shapes, numbers, operations, elements, and/or groups thereof. As used herein, the term “and/or” includes any and all combinations of one or more of the associated listed items.

It will be understood that although the terms “first”, “second”, etc. may be used herein to describe various components, these components should not be limited by these terms. The terms do not mean a particular order, top and bottom, or superiority but are only used to distinguish one component from another. Accordingly, a first element, area, or portion that will be described below may indicate a second element, area, or portion without deviating from teachings of the present invention.

Hereinafter, the embodiments of the present invention will be described with reference to schematic drawings. In the drawings, for example, according to manufacturing technologies and/or tolerances, illustrated shapes may be modified. Accordingly, the embodiments of the present invention will not be understood to be limited to certain shapes of illustrated areas but will include variances in shapes caused while being manufactured.

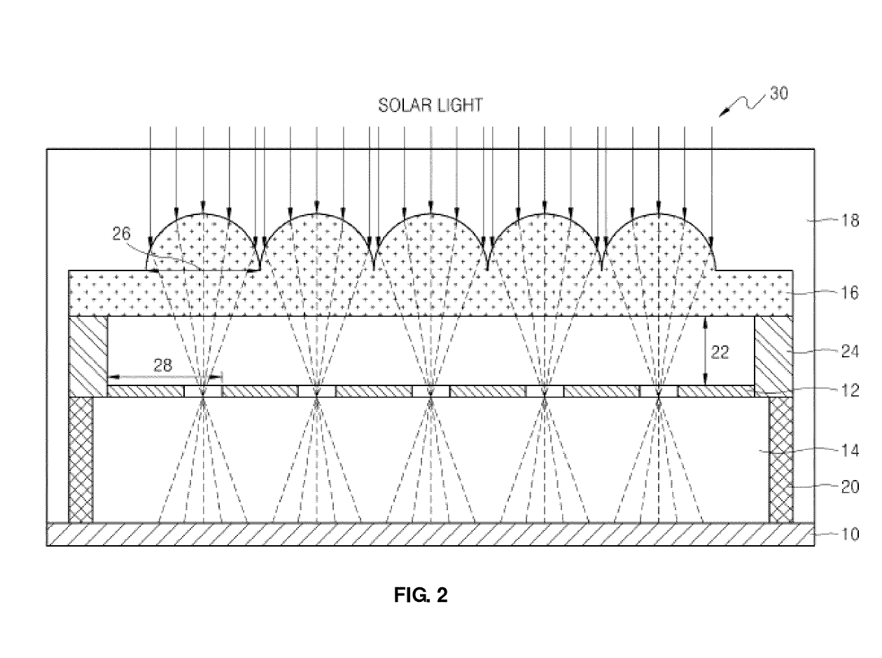

FIG. 2 is a cross-sectional view of a solar cell 30 including a condensing micro lens array 16 according to an embodiment of the present invention.

Referring to FIG. 2, the solar cell 30 including the condensing micro lens array 16 includes a lower electrode 10, an upper opaque metal grid electrode 12, a photoactive layer 14, the micro lens array 16, a sealing member 18, and an optical spacer 24.

The photoactive layer 14 includes a top formed with the upper opaque metal grid electrode 12 and a bottom end disposed on the lower electrode 10, which is a semiconductor layer formed of III-V compound semiconductors to absorb solar light and to cause photo-electric conversion. As an example, the photoactive layer 14 may be formed of gallium arsenic (GaAs) semiconductors.

The micro lens array 16 is disposed while forming a certain gap from the top of the photoactive layer 14 and refracts solar light passing through the transparent sealing member 18. As an example, the micro lens array 16 may be formed of quartz and high polymers.

The sealing member 18, on the lower electrode 10, surrounds the photoactive layer 14 and the micro lens array 16 and transmits solar light.

The optical spacer 24 includes a top closely attached to a bottom surface of the micro lens array 16 to allow the micro lens array 16 to be disposed forming a certain gap 22 from the top of the photoactive layer 14 and a bottom end closely attached to the top of the photoactive layer 14 to support the micro lens array 16. Accordingly, the micro lens array 16 supported by the optical spacer 24 is disposed forming the gap 22 from the top of the photoactive layer 14 while being closely coupled with the sealing member 18 at the same time.

In this case, the gap 22 between the top of the photoactive layer 14 and the micro lens array 16 may be identical to a distance between the top of the photoactive layer 14 and a height of the micro lens array 16 to minimize an area of a spot formed on the top of the photoactive layer 14 by allowing the micro lens array 16 to refract solar light incident upon the micro lens array 16.

That is, the size of the optical spacer 24 is identical to the gap 22 between the top of the photoactive layer 14 and the micro lens array 16.

The gap 22 between the top of the photoactive layer 14 and the micro lens array 16 may vary with a type of the micro lens array 16.

The micro lens array 16 may include a plurality of micro lenses having a truncated spherical shape to refract solar light incident upon a top surface thereof or a plurality of micro lenses having a truncated cylindrical shape to refract the solar light incident upon the top surface.

Herein, when the plurality of micro spherical lenses are formed on the top surface of the micro lens array 16, the plurality of micro spherical lenses may be formed on the top surface of the micro lens array 14 to allow a distance between adjacent micro spherical lenses to be “0”.

That is, an array of the plurality of micro spherical lenses covers the photoactive layer 14 and a size 26 of one micro spherical lens may be identical to a value 28 obtained by adding a gap of the upper opaque metal grid electrode 12 and a size of the upper opaque metal grid electrode 12 (refer to FIG. 2, a horizontal length of a cross section of the upper opaque metal grid electrode 12). Accordingly, solar light condensed by the micro spherical lens passes through the upper opaque metal grid electrode 12 formed on the top of the photoactive layer 14 and is transferred to the photoactive layer 14, thereby minutely controlling the solar light.

The gap 22 between the bottom surface of the micro lens array 16 formed with the plurality of micro spherical lenses and the top of the photoactive layer 14 may be 900 μm. The gap 22 is the height for reducing the area of spot formed on the top of the photoactive layer 14 by allowing the micro spherical lenses to refract the solar light incident upon the micro lens array 16 formed with the micro spherical lenses, which is a result obtained through repetitive experiments.

On the other hand, when the plurality of micro cylindrical lenses are formed on the top surface of the micro lens array 16, the micro cylindrical lenses may be formed on the top surface of the micro lens array 14 to allow a distance between adjacent micro cylindrical lenses to be “0”.

That is, an array of the plurality of micro cylindrical lenses covers the photoactive layer 14. A size 26 of one micro cylindrical lens may be identical to a gap 28 of the upper opaque metal grid electrode 12. Accordingly, solar light condensed by the micro cylindrical lens passes through the upper opaque metal grid electrode 12 formed on the top of the photoactive layer 14 and is transferred to the photoactive layer 14, thereby minutely controlling the solar light.

The gap 22 between the bottom surface of the micro lens array 16 formed with the plurality of micro cylindrical lenses and the top of the photoactive layer 14 may be 600 μm. The gap 22 is the height for reducing the area of spot formed on the top of the photoactive layer 14 by allowing the micro spherical lenses to refract the solar light incident upon the micro lens array 16 formed with the micro cylindrical lenses, which is a result obtained through repetitive experiments.

In addition, the solar cell 30 may further include a sealing member 20 surrounding the photoactive layer 14. The sealing member 20 protects the photoactive layer 14 from external efficiency-degrading factors such as humidity in the air and physical impact.

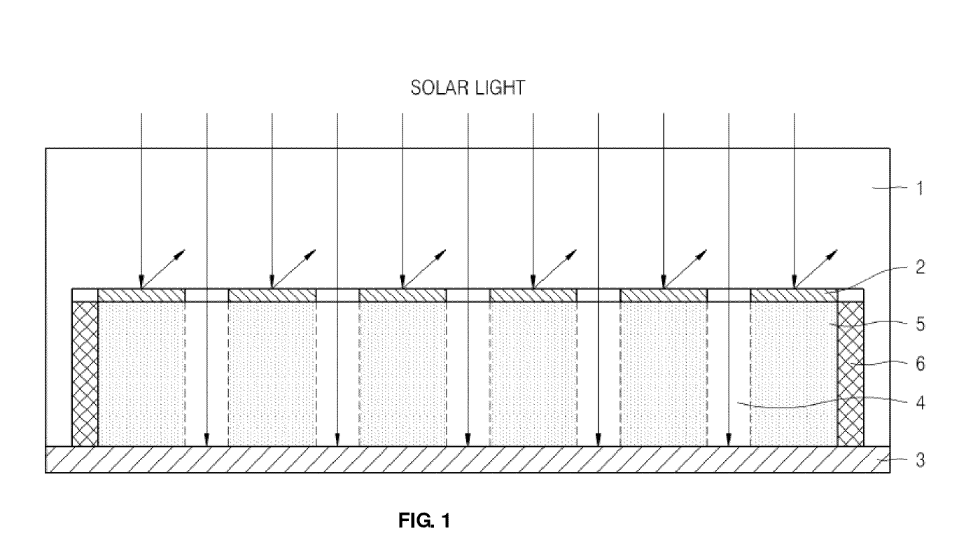

Accordingly, as shown in FIG. 2, when replacing a general cover 1 shown in FIG. 1 by the micro lens array 16, a loss in light occurring in a solar cell of FIG. 1 may be reduced by minutely controlling solar light.

That is, parallel rays heading for the upper opaque metal grid electrode 12 are refracted toward an area of the photoactive layer 14 between electrodes, thereby reducing a loss in light reflected by the upper opaque metal grid electrode 12. The light refracted by the micro lens array 16 arrive evenly to the inside of the photoactive layer 14, thereby minimizing a loss caused by a shadow effect generated on a lower portion of the upper opaque metal grid electrode 12. Also, a lens condensing effect generated by optimally using the optical spacer 24 contributes to the generation of an active photoelectric current, thereby allowing an overall increase in the solar cell.

The gap 22 between the micro lens array 16 and the top of the photoactive layer 14 may be optimal when a focus of light refracted by the micro lenses of the micro lens array 16 is formed precisely on a surface of the top of the photoactive layer 14. While actually manufacturing the solar cell 30, the optical spacer 24 may be formed of transparent high polymers on an edge of the photoactive layer 14 to allow the focus of the light refracted by the micro lenses of the micro lens array 16 to be precisely formed on the surface of the top of the photoactive layer 14 and to allow the micro lens array 16 to be disposed with a certain distance from the top of the photoactive layer 14.

Also, a distance between the micro lens array 18 and the surface of the top of the photoactive layer 14 is precisely adjusted using a micrometer, in which the micro lens array 16 is closely coupled with sealing member 18, thereby disposing the micro lens array 16 with a certain distance from the top of the photoactive layer 14 to allow the focus of the light refracted by the micro lenses of the micro lens array 16 to be precisely formed on the surface of the top of the photoactive layer 14 without the optical spacer 24.

Herein, it is necessary that the sealing member 18 has a shape capable of containing a plurality of micro lenses formed on the top of the micro lens array 16. For this, the sealing member 18 may be formed of quartz, in which the quartz is wet-etched to allow the sealing member 18 to have the shape capable of containing the plurality of micro lenses. After that, the micro lens array 16 may be formed by coating the wet-etched sealing member 18 with an ultraviolet (UV) curing agent or by spin coating the wet-etched sealing member 18. According thereto, the micro lens array 16 and the sealing member 18 may be formed as a single body. The sealing member 18 formed as the single body with the micro lens array 16 functions as a substrate for forming the micro lens array 16 and the sealing member 18 at the same time. The micro lens array 16 functions as a layer for refracting solar light. Also, the micro lens array 16 may be formed of any material having a refraction coefficient from about 1.46 to about 1.606.

When the gap 22 between the micro lens array 16 and the top of the photoactive layer 14 is controlled using two types described above, that is, when controlling a distance between the micro lens array 16 and the surface of the top of the photoactive layer 14, as a result of analyzing photoelectric characteristics of the solar cell 30, there is no difference between the photoelectric characteristics of solar cells of the two different types.

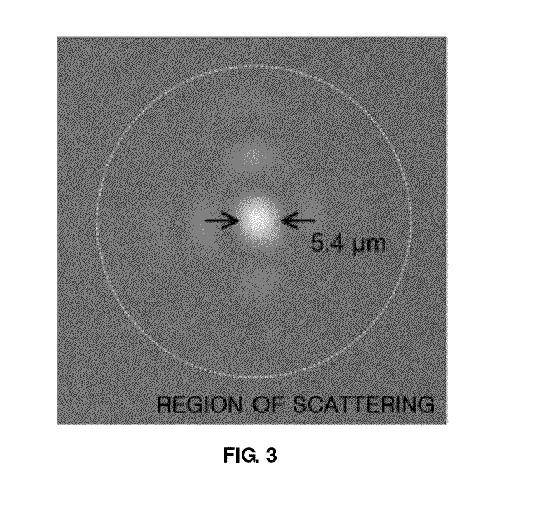

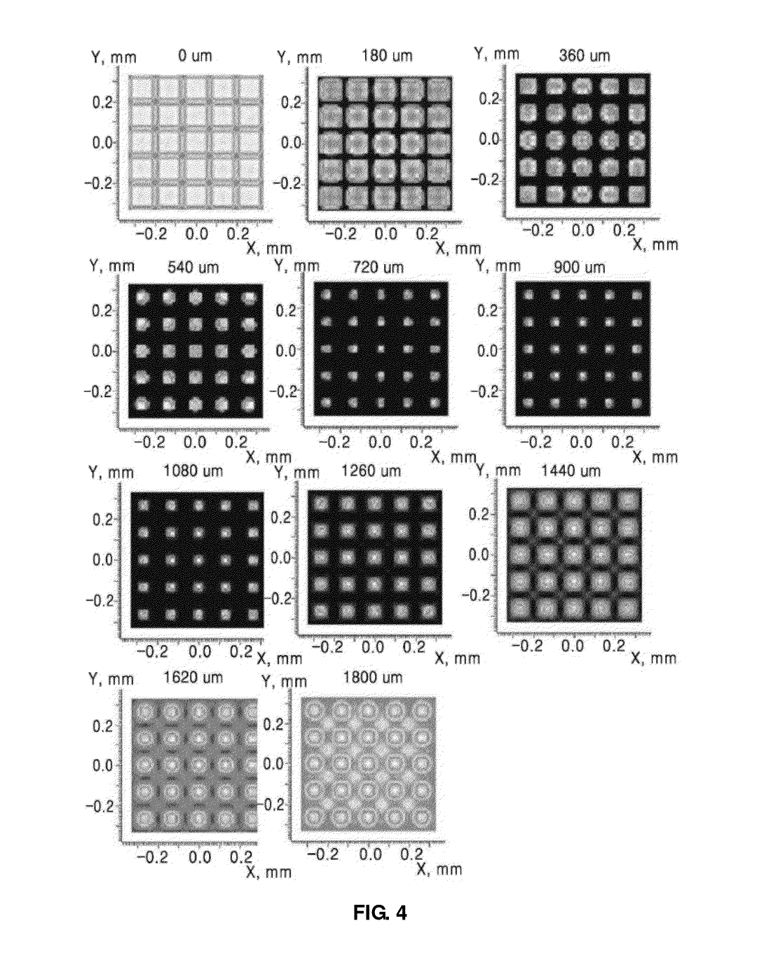

FIG. 3 is a photograph illustrating a focus formed on a charge-coupled device (CCD) by parallel rays passing through the micro lens array 16 shown in FIG. 2. FIG. 4 is a view illustrating this. Referring to FIG. 4, when measuring a focal length using He-Ne laser having a wavelength of about 632.8 nm, the micro lens array 16 shows a focal length of about 900 μm and uniform light refraction ability on the entire surface of the lens. Herein, the micro lens array 16 of FIG. 2 may include the plurality of micro spherical lenses.

It can be recognized that an optical spot passing through the micro lens array 16 formed with the plurality of micro spherical lenses and then condensed into the CCD is not an ideal spot but has a diameter of about 5.4 μm. Also, it can be seen that condensed light is scattered in a shape according to Gaussian distribution. When including an area formed by scattering, a range formed by the condensed light is from about 1 to about 40 μm. When the gap of the upper opaque metal grid electrode 12 shown in FIG. 2 is greater than this, it is possible to effectively operate. Accordingly, since commercialized solar cells have a grid electrode with a width and a gap of from about 1 to about 10 μm and from about 1 to about 100 μm, it is possible to be applied without limitation in application within a general range.

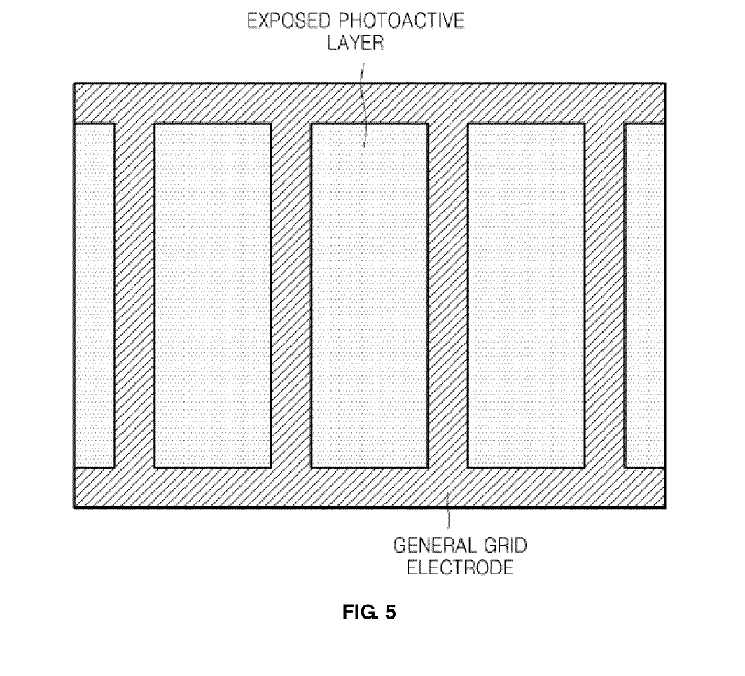

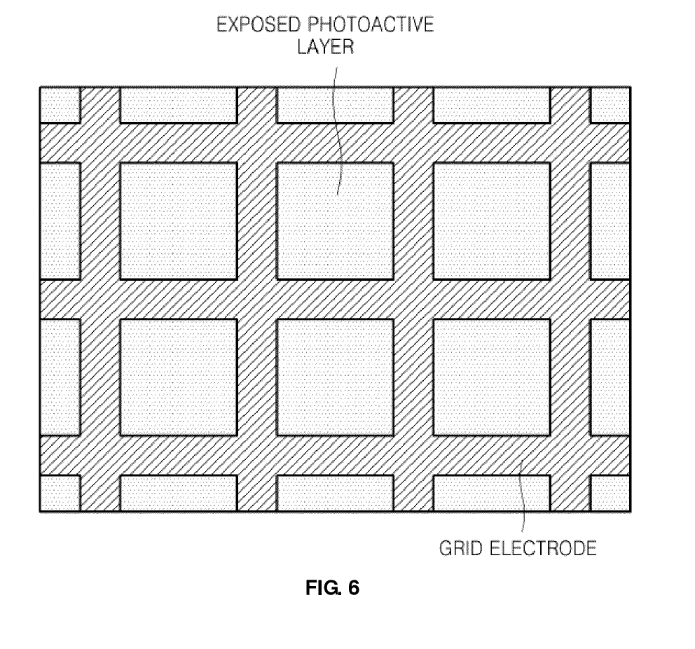

FIG. 5 is a view of an upper opaque grid electrode according to an embodiment of the present invention. FIG. 6 is a view of an upper opaque grid electrode according to another embodiment of the present invention.

FIG. 5 illustrates a general upper opaque grid electrode array, and FIG. 6 illustrates an upper opaque grid electrode arranged densely to increase electric properties.

An upper opaque grid electrode array of a solar cell used to test the performance of the solar cell 30 is identical to that of FIG. 5, which is generally used for a general solar light device design. When densely arranging an upper opaque grid electrode as shown in FIG. 6, electric properties increase due to an increase in a contact surface between a photoactive layer and the upper opaque grid electrode. However, in this case, as described above, an amount of light reflected by the upper opaque grid electrode increases and a loss in light efficiency is caused due to an increase in a shade area below the upper opaque grid electrode, thereby generating a loss in photo-electric conversion efficiency, greater than the increase in electric properties, which is inefficient as a result thereof. However, when applying technology of minutely controlling solar light using the micro lens array 16, that is, when the micro lens array 16 is disposed to have a certain gap from the top of the photoactive layer 14 to minimize an area of spot formed on the top of the photoactive layer by using solar light incident upon the micro lens array 16 and refracted thereby, it is possible to minimize a loss in solar light without loss in electric properties, thereby effectively operating in the upper opaque grid electrode array shown in FIG. 6. That is, in upper opaque grid electrodes arranged in any shape, it is possible to identically or more effectively operate.

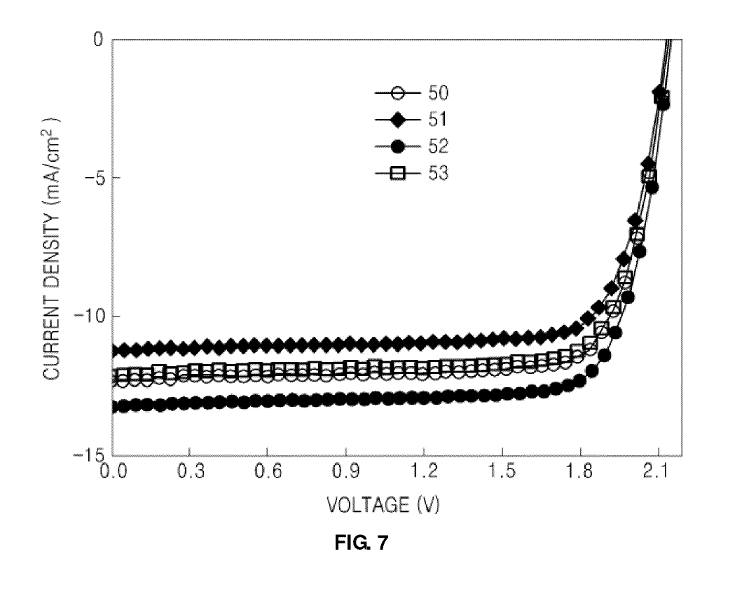

FIG. 7 is a view of current-voltage characteristic curves of solar cells mounted with a condensing micro lens arrays.

A solar cell 50 mounted with a condensing micro lens array shows higher current characteristics than a solar cell 51 mounted with general glass. Particularly, a solar cell 52 including the micro lens array 16 disposed to have the certain gap 22 from the surface of the top of the photoactive layer 14 to minimize a size of a spot area formed on the surface of the top of the photoactive layer 14 by using light penetrating the micro lens array 16, all characteristics rapidly increase and even efficiency more increases by about 10% than a solar cell 53 with no sealing layer.

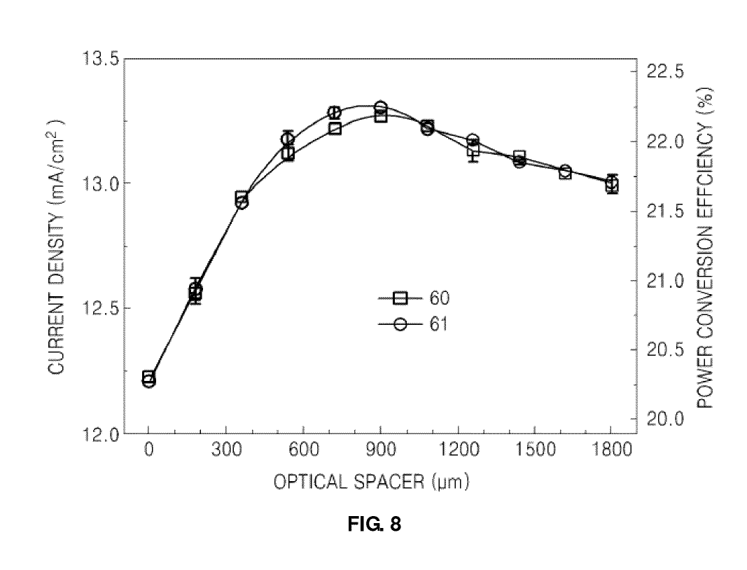

FIG. 8 illustrates current density and efficiency variation curves in the solar cell according to heights according to certain gaps between a micro lens array and a surface of a top of a photoactive layer.

A space for allowing light passing through the micro lens array to be refracted is provided, thereby rapidly increasing current density 60. According thereto, power conversion efficiency 61 increases in the same way. When setting the gap to be identical to a focal length due to the active generation of exitons by condensing light, it can be checked that photo-electric characteristics reach zenith thereof.

As described above, exemplary embodiments of the present invention have been described. While the present invention has been particularly shown and described with reference to exemplary embodiments thereof, it will be understood by those of ordinary skill in the art that various changes in form and details may be made therein without departing from the spirit and scope of the present invention as defined by the following claims. Therefore, the disclosed embodiments will be considered in the view of description not in the view of limitation. Accordingly, the scope of the present invention will not be limited to the embodiments described above but will be understood to include the contents disclosed in the claims and various equivalents thereof.

### INDUSTRIAL APPLICABILITY

The present invention may be used to develop solar cells.

1. A solar cell comprising a condensing micro lens array, the solar cell comprising:
a lower electrode;
a photoactive layer comprising a top formed with an upper opaque metal grid electrode and a bottom end disposed on the lower electrode, the photoactive layer being formed of III-V compound semiconductors to absorb solar light to generate photo-electric conversion; and
the micro lens array disposed to have a certain gap from the top of the photoactive layer and refracting incident solar light toward the photoactive layer.

2. The solar cell of claim 1, wherein the gap between the photoactive layer and the micro lens array is identical to a distance between the top of the photoactive layer and a height of the micro lens array to reduce an area of a spot formed on the top of the photoactive layer by allowing the micro lens array to refract the solar light incident upon the micro lens array.

3. The solar cell of claim 2, wherein the micro lens array comprises a plurality of micro lenses having a truncated spherical shape refracting solar light incident upon a top surface of the micro lens array.

4. The solar cell of claim 3, wherein the plurality of micro spherical lenses are formed on the top surface of the micro lens array to allow a distance between adjacent micro spherical lenses to be “0”, respectively.

5. The solar cell of claim 3, wherein a gap between a bottom surface of the micro lens array formed with the plurality of micro spherical lenses and the top of the photoactive layer is 900 μm.

6. The solar cell of claim 2, wherein the micro lens array comprises a plurality of micro lenses having a truncated cylindrical shape refracting solar light incident upon a top surface of the micro lens array.

7. The solar cell of claim 6, wherein the plurality of micro cylindrical lenses are formed on the top surface of the micro lens array to allow a distance between adjacent micro cylindrical lenses to be “0”, respectively.

8. The solar cell of claim 6, wherein a gap between a bottom surface of the micro lens array formed with the plurality of micro cylindrical lenses and the top of the photoactive layer is 600 μm.

9. The solar cell of claim 1, further comprising a sealing member, formed on the lower electrode, surrounding the photoactive layer and the micro lens array and transmitting solar light.

10. The solar cell of claim 9, wherein the micro lens array is disposed to be closely coupled with an inner surface of the sealing member and to form a gap from the top of the photoactive layer.

11. The solar cell of claim 1, further comprising an optical spacer comprising a top closely attached to the bottom surface of the micro lens array and a bottom closely attached to the top of the photoactive layer to support micro lens array to allow the micro lens array to be disposed to form the certain gap from the top of the photoactive layer.
